(19) United States
(12) Patent Application Publication
(10) Pub. No.: US 2025/0031475 A1
(43) Pub. Date: Jan. 23, 2025

(54) SEMICONDUCTOR CHIP, SOLID-STATE IMAGING DEVICE, AND ELECTRONIC EQUIPMENT

(71) Applicant: SONY SEMICONDUCTOR SOLUTIONS CORPORATION, Kanagawa (JP)

(72) Inventor: Hitoshi OKANO, Kanagawa (JP)

(73) Assignee: SONY SEMICONDUCTOR SOLUTIONS CORPORATION, Kanagawa (JP)

(21) Appl. No.: 18/684,320

(22) PCT Filed: Mar. 25, 2022
(86) PCT No.: PCT/JP2022/014218

§ 371 Date: Feb. 16, 2024

(30) Foreign Application Priority Data
Aug. 24, 2021 (JP) 2021-136675

(51) Int. Cl. H01L 27/146; H01L 23/00

(52) U.S. Cl. CPC H01L 27/14634; H01L 24/08; H01L 24/80; H01L 27/1469; H01L 2224/08145; H01L 2224/80895; H01L 2224/80896

(57) ABSTRACT

Provided is a semiconductor chip, a solid-state imaging device, and electronic equipment which achieve further reduction in thickness of a silicon substrate, required for 3D staking and which have a structure with no effect on device characteristics. Such a configuration having a first semiconductor chip including photodiodes, a second semiconductor chip including a signal processing circuit from the photodiodes and which is stacked on the first semiconductor chip, a first insulating film which is stacked on a second surface of the second semiconductor chip that is opposite to a first surface thereof having the first semiconductor chip stacked thereon and which includes oxygen, and a second insulating film which is stacked on the first insulating film and which includes oxygen are made, thereby preventing occurrence of leakage at a depletion layer of a transistor in the semiconductor chip and achieving reduction in film thickness.

### TECHNICAL FIELD

The present disclosure relates to a semiconductor chip having a 3D stacked structure, a solid-state imaging device, and electronic equipment adopting the semiconductor chip and the solid-state imaging device.

### BACKGROUND ART

In recent years, for example, in a semiconductor device such as a memory or a sensor, in order to achieve increase in circuit scale and higher functionality, a three-dimensional stacking (hereinafter referred to as 3D stacking) technique in which these circuits are incorporated in a single chip has been developed. As a method of carrying out 3D stacking, such techniques as connection of using bumps, through silicon vias (TSV: Through Silicon Via, that is hereinafter called a “TSV”), or copper-copper bonding (that is hereinafter called “Cu—Cu bonding”) that is a direct connection between components have been used. Also, these methods allow a sensor chip, a logic chip, a memory chip, and other components are three-dimensionally stacked.

In addition, for example, a chip on wafer (CoW: Chip On Wafer, hereinafter referred to as “CoW”) structure in which a semiconductor wafer such as a sensor circuit and a chip such as a logic circuit are bonded to each other and a structure in which, for example, a semiconductor wafer such as a sensor circuit and a semiconductor wafer such as a logic circuit are bonded to each other by use of Cu—Cu bonding (WOW: Wafer On Wafer, hereinafter referred to as a “WOW”) to thereby have each sensor chip on the wafer and a logic chip on the other wafer stacked on top of another have also been conceived of. These 3D stacking structures are assumed to be a stacked structure having not only two layers, but also multiple layers. In addition, connection between wafers (or chips) vertically stacked in multiple layers is made through TSVs penetrating a silicon (Si) substrate, for example.

However, as a chip has a greater number of layers formed therein, its film thickness becomes larger. Owing to this, the larger a thickness of the chip, the greater a diameter of the TSV. As a result, an effect of the TSV on a chip area becomes large in design. In addition, in CoW, when a step between the chips becomes greater, a problem in processing and an effect on throughput are unignorable.

In view of this, it is preferred that the film thickness of the chip be formed as thin as possible.

To address such a problem, such a technique relating to a back-illuminated solid-state imaging device, a method of manufacturing a back-illuminated solid-state imaging device, an imaging device and electronic equipment using such a solid-state imaging device has been disclosed. In this technique, singulated memory circuits and singulated logic circuits are laid out on a wafer in a horizontal direction, embedded by an oxide film, and planarized so as to be reduced in height, and then are stacked under a lower surface of a solid-state imaging element such that the memory circuits and the logic circuits are arranged in a plan direction in a range in which the solid-state imaging element is present.

### CITATION LIST

### Patent Literature

PTL 1: International Publication No. WO 2019-087764

### SUMMARY

### Technical Problem

However, in a technique disclosed in PTL 1, the 3D stacking (WoW or CoW) described above, in a case in which a lower surface of a silicon substrate is polished to reduce a thickness of the silicon substrate, when a depletion layer of a transistor which extends from a front surface side of the silicon substrate reaches a defect arising from the polishing or contamination in the vicinity of this polished surface, leakage increases via this defect.

In other words, a width of a typical depletion layer is a function of the impurity concentration, and in a case in which this width is larger than a thickness of the polished silicon substrate, leakage may occur through the defect.

The present disclosure has been made in view of the above problem, and an object of the present disclosure is to provide a semiconductor chip, a solid-state imaging device, and electronic equipment which have a structure allowing a thickness of a silicon substrate required for 3D stacking to be further reduced and having no effect on device characteristics.

### Solution to Problem

The present disclosure has been made in order to solve the above problem, and according to a first aspect thereof, there is a solid-state imaging device including a first semiconductor chip including photodiodes, a second semiconductor chip including a signal processing circuit from the photodiodes and which is stacked on the first semiconductor chip, a first insulating film which is stacked on a second surface of the second semiconductor chip that is opposite to a first surface thereof having the first semiconductor chip stacked thereon and which includes oxygen, and a second insulating film stacked on the first insulating film and including oxygen.

In addition, in the first aspect, the second insulating film may include a High-k dielectric having an oxygen surface density different from the first insulating film.

In addition, in the first aspect, the second insulating film stacked on the first insulating film may include a negative insulating film or a positive insulating film.

In addition, in the first aspect, a third insulating film including a High-k dielectric may be stacked on the second insulating film.

In addition, in the first aspect, the second insulating film may include hafnium oxide (HfO₂), aluminum oxide (Al₂O₃), zirconium oxide (ZrO₂), tantalum pentoxide (Ta₂O₅), titanium oxide (TiO₂), lanthanum oxide (La₂O₃), or yttrium oxide (Y₂O₃).

In addition, in the first aspect, the second insulating film may be stacked on a buried oxide film layer (BOX layer).

In addition, in the first aspect, the solid-state imaging device may include a third semiconductor chip having a semiconductor active element and in which the first insulating film and the second insulating film are stacked, in the first semiconductor chip or the second semiconductor chip.

In addition, in the first aspect, two or more semiconductor chips may be stacked on the first semiconductor chip.

According to a second aspect, there is a solid-state imaging device including a semiconductor chip including photodiodes, a first insulating film stacked on an upper surface of the photodiodes on a light incidence surface side of the semiconductor chip and including oxygen, and a negative or a positive second insulating film stacked on the first insulating film and including oxygen.

According to a third aspect, there is a semiconductor chip including a substrate having a polished surface, a first insulating film formed on the polished surface and including oxygen, a second insulating film stacked on the first insulating film and including oxygen, and a semiconductor active element.

In addition, in the third aspect, a second semiconductor chip may be bonded to a surface that is opposite to the polished surface.

According to a fourth aspect, there is electronic equipment including a solid-state imaging device including a first semiconductor chip including photodiodes, a second semiconductor chip including a signal processing circuit from the photodiodes and which is stacked on the first semiconductor chip, a first insulating film which is stacked on a second surface of the second semiconductor chip that is opposite to a first surface thereof having the first semiconductor chip stacked thereon and which includes oxygen, and a second insulating film stacked on the first insulating film and including oxygen, or a semiconductor chip including a polished surface, a first insulating film stacked on the polished surface and including oxygen, a second insulating film stacked on the first insulating film and including oxygen, and a semiconductor active element.

By adopting the above aspects, it is possible to provide a semiconductor chip, a solid-state imaging device, and electronic equipment which have a structure allowing further reduction in thickness of a silicon substrate required for 3D stacking and having no effect on device characteristics.

### BRIEF DESCRIPTION OF DRAWINGS

FIG. 1 is a cross-sectional view partially illustrating a schematic structure of a solid-state imaging device according to a first embodiment of the present disclosure.

FIG. 2 is a cross-sectional view partially illustrating a schematic structure of a solid-state imaging device according to a comparative example.

FIG. 3 is a diagram of assistance in explaining leakage of the solid-state imaging device according to the comparative example.

FIG. 4 is a diagram of assistance in explaining prevention of leakage of the solid-state imaging device according to the present disclosure.

FIG. 5 is a cross-sectional view partially illustrating a schematic structure of a basic form of a solid-state imaging device according to a second embodiment of the present disclosure.

FIG. 6 is a cross-sectional view partially illustrating a schematic structure of a solid-state imaging device according to a first modification example of the second embodiment of the present disclosure.

FIG. 7 is a cross-sectional view partially illustrating a schematic structure of a solid-state imaging device according to a second modification example of the second embodiment of the present disclosure.

FIG. 8 is a cross-sectional view partially illustrating a schematic structure of a solid-state imaging device according to a third embodiment of the present disclosure.

FIG. 9 is a cross-sectional view partially illustrating a schematic structure of a solid-state imaging device according to a fourth embodiment of the present disclosure.

FIG. 10 is a cross-sectional view partially illustrating a schematic structure of a solid-state imaging device according to a fifth embodiment of the present disclosure.

FIG. 11 is a cross-sectional view partially illustrating a schematic structure of a solid-state imaging device according to a sixth embodiment of the present disclosure.

FIG. 12 is a diagram of assistance in explaining a method of manufacturing the solid-state imaging device according to the present disclosure (1).

FIG. 13 is a diagram of assistance in explaining the method of manufacturing the solid-state imaging device according to the present disclosure (2).

FIG. 14 is a diagram of assistance in explaining the method of manufacturing the solid-state imaging device according to the present disclosure (3).

FIG. 15 is a diagram of assistance in explaining the method of manufacturing the solid-state imaging device according to the present disclosure (4).

FIG. 16 is a diagram of assistance in explaining the method of manufacturing the solid-state imaging device according to the present disclosure (5).

FIG. 17 is a diagram of assistance in explaining the method of manufacturing the solid-state imaging device according to the present disclosure (6).

FIG. 18 is a diagram of assistance in explaining the method of manufacturing the solid-state imaging device according to the present disclosure (7).

FIG. 19 is a diagram of assistance in explaining the method of manufacturing the solid-state imaging device according to the present disclosure (8).

FIG. 20 is a block diagram illustrating a configuration example of electronic equipment provided with the solid-state imaging device according to the embodiments of the present disclosure.

### DESCRIPTION OF EMBODIMENTS

Hereinafter, modes for carrying out the present disclosure (hereinafter referred to as “embodiments”) will be described in the following order with reference to the accompanying drawings. In the drawings, identical or similar parts will be denoted by the same or similar reference signs. Since the drawings are schematically illustrated, it should be noted that ratios of dimensions of respective sections or the like do not necessarily coincide with the actual ones. It goes without saying that the drawings are sometimes different from each other in dimensional relation or ratio.
1. First embodiment of solid-state imaging device according to present disclosure
2. Basic form of second embodiment of solid-state imaging device according to present disclosure
3. First modification example of second embodiment of solid-state imaging device according to present disclosure
4. Second modification example of second embodiment of solid-state imaging device according to present disclosure
5. Third embodiment of solid-state imaging device according to present disclosure
6. Fourth embodiment of solid-state imaging device of present disclosure
7. Fifth embodiment of solid-state imaging device according to present disclosure
8. Sixth embodiment of solid-state imaging device according to present disclosure
9. Method of manufacturing solid-state imaging device according to present disclosure
10. Configuration example of electronic equipment

### 1. First Embodiment of Solid-State Imaging Device According to Present Disclosure

### (Configuration of First Embodiment)

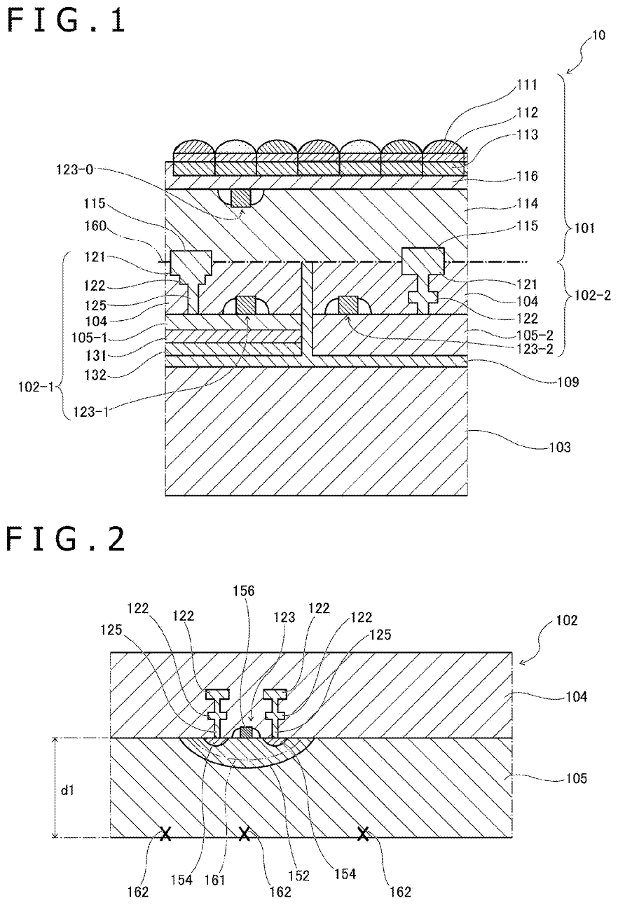

Hereinafter, with reference to FIG. 1, a first embodiment of a solid-state imaging device 10 according to the present disclosure will be described. FIG. 1 is a cross-sectional view partially illustrating a schematic structure of the solid-state imaging device 10 according to the first embodiment of the present disclosure. As illustrated in FIG. 1, the solid-state imaging device 10 includes two logic chips 102-1 and 102-2 stacked on a support substrate 103, and a CMOS image sensor (CIS: CMOS Image Sensor, hereinafter, referred to as a “CIS”) chip 101 stacked on the logic chips 102-1 and 102-2. In FIG. 1, an upper side is a light incidence surface side. Thus, the CIS chip 101 is stacked on the light incidence surface side.

The CIS chip 101 has a photodiode formation layer 116 having a plurality of photodiodes 113 formed therein, and a wiring layer 114 for wiring the photodiodes, for example, as illustrated in FIG. 1. In addition, an upper surface of each of the photodiodes 113 on the light incidence surface side of the CIS chip 101 has a color filter 112 stacked thereon, and further, an upper surface of each of the color filters 112 has an on-chip lens 111 stacked thereon. Note that “upper” such as an “upper surface” or “lower” such as a “lower surface” in the following description indicate up or down in the drawings, respectively.

The support substrate 103 is a silicon film constituting a base plate of the solid-state imaging device 10. The support substrate 103 has two semiconductor chips such as the logic chips 102-1 and 102-2 stacked thereon. The logic chips 102-1 and 102-2 have a logic circuit, a memory circuit (both not illustrated), and the like formed therein. The logic circuit is, for example, a vertical drive section, a horizontal drive section, a system control section, a signal processing section, or the like for sequentially reading out image data of each pixel including the photodiode 113. In addition, the memory circuit is, for example, a data storing section or the like which temporarily stores data necessary for processing by the signal processing section. These logic circuits are accommodated by being divided into the logic chips 102-1 and 102-2.

Note that, in the following description, the logic chip and the memory chip are collectively denoted as a “logic chip” for description.

The logic chip 102-1 has a transistor 123-1 disposed on a silicon substrate 105-1. Also, above the transistor 123-1, a multilayer wiring layer 104 in which an interlayer insulating film is formed is disposed, and each wiring layer in the multilayer wiring layer 104 has a wire 122 formed therein, and the wire 122 includes a half of circuits such as the vertical drive section and the horizontal drive section described above. In addition, the upper and lower sides of the wires 122 are connected to each other through vias 125 in an up-down direction (in a vertical direction in FIG. 1). In addition, on a lower side of the logic chip 102-1, as illustrated in FIG. 1, an oxide film 131 and a charged film 132 are stacked in this order.

In the logic chip 102-2, the rest of the logic circuits which are not accommodated in the logic chip 102-1 is formed on a silicon substrate 105-2. More specifically, as in the logic chip 102-1, a transistor 123-2 is disposed on the silicon substrate 105-2. Also, above the transistor 123-2, the multilayer wiring layer 104 in which the interlayer insulating film is formed is disposed, and each of the wiring layers in the multilayer wiring layer 104 has the wire 122 formed therein, and the wire 122 includes the circuits such as the vertical drive section and the horizontal drive section. In addition, the upper and lower sides of the wires 122 are connected to each other, as in the logic chip 102-1. Moreover, the logic chips 102-1 and 102-2 are insulated from each other with an insulating film 109 interposed therebetween.

Note that, in FIG. 1, an example in which the two logic chips 102-1 and 102-2 are disposed on the support substrate 103 has been described, but the logic chip is not limited to two and may be one or two or more. In addition, an example in which one transistor 123-1 and one transistor 123-2 are disposed in the respective logic chips 102-1 and 102-2 is illustrated; however, in actual implementation, a large number of transistors 123 are disposed in each of the logic chips 102-1 and 102-2.

The logic chips 102-1 and 102-2 have respective pads 121 formed therein on a side where the CIS chip 101 is bonded to each of the logic chips 102-1 and 102-2, the pads 121 being conductors such as copper (Cu). In addition, the CIS chip 101 similarly has pads 115 formed therein on such a side as to be bonded to each of the logic chips 102-1 and 102-2, the pads 115 being conductors such as copper (Cu). Then, the pad 115 and the pad 121 are disposed so as to be opposed to each other on the side where they are bonded to each other.

Accordingly, when the CIS chip 101 is stacked on the logic chips 102-1 and 102-2, the respective pads 121 formed in the logic chips 102-1 and 102-2 are bonded to the respective pads 115 disposed to be opposed thereto by Cu—Cu bonding at the bonding surface 160.

Since the pad 121 and the pad 115 each include the conductor such as copper (Cu), the circuits formed in the CIS chip 101 and the circuits formed in the logic chip 102 are electrically connected with each other by Cu—Cu bonding between the pads 115 and the corresponding pads 121 at the bonding surface 160, thereby forming circuits.

Note that it is sufficient if only the required number of pads 115 and only the required number of pads 121 are provided at positions required to connect the circuits formed in the CIS chip 101 with the circuits formed in the logic chips 102-1 and 102-2.

### (Actions of Oxide Film and Charged Film)

As illustrated in FIG. 1, the lower surface of the logic chip 102-1 has the oxide film 131 and the charged film 132 stacked thereon on such a side as to be opposed to the support substrate 103. When a lower surface of the silicon substrate 105-1 is polished in order to form the logic chip 102-1 to be thin, leakage may occur from a depletion layer 161 of the transistor 123-1.

The oxide film 131 and the charged film 132 prevent the occurrence of leakage at the depletion layer 161 attributable to polishing of the lower surface of the silicon substrate 105-1. This will be described below.

FIG. 2 is a view of the logic chip 102 obtained by polishing the lower surface of the logic chip 102 to be made thin. As illustrated in FIG. 2, the film thickness of the logic chip 102 is formed to be d1 by polishing in order to achieve a low height. However, when the lower surface of the silicon substrate 105 is polished, defects 162 (× in FIG. 2) attributable to polishing or contamination occur in the vicinity of the polished surface thereof. In these defects 162, for example, an electron 164 or a hole 163 occurs depending on types or concentrations of impurities of the silicon substrate 105, or the like.

Incidentally, in FIG. 2, in a case in which the transistor 123 is a P type, a drain and a source are formed by respective P+ diffusion layers 154, and a gate 156 is disposed between the P+ diffusion layers 154. These circuits are connected to each circuit through the vias 125 and the wires 122. In addition, around the P+ diffusion layers 154 in the silicon substrate 105, there is formed an N well 152. In addition, the depletion layer 161 is formed from the N well 152 to a peripheral P-type substrate side with a low impurity concentration.

However, as illustrated in FIG, 2, if the film thickness d1 is formed to be thick, a distance between the N well (N-well) 152 in the P-type transistor 123 disposed on the upper surface of the silicon substrate 105 and the defect 162 becomes large. Hence, the depletion layer 161 of the transistor 123 does not reach the defect 162. Accordingly, there is no possibility that the electrons 164 caught by the defects 162 enter the depletion layer 161, thereby causing leakage from the depletion layer 161. This similarly applies to a case in which the transistor 123 disposed on the upper surface of the silicon substrate 105 is an N type.

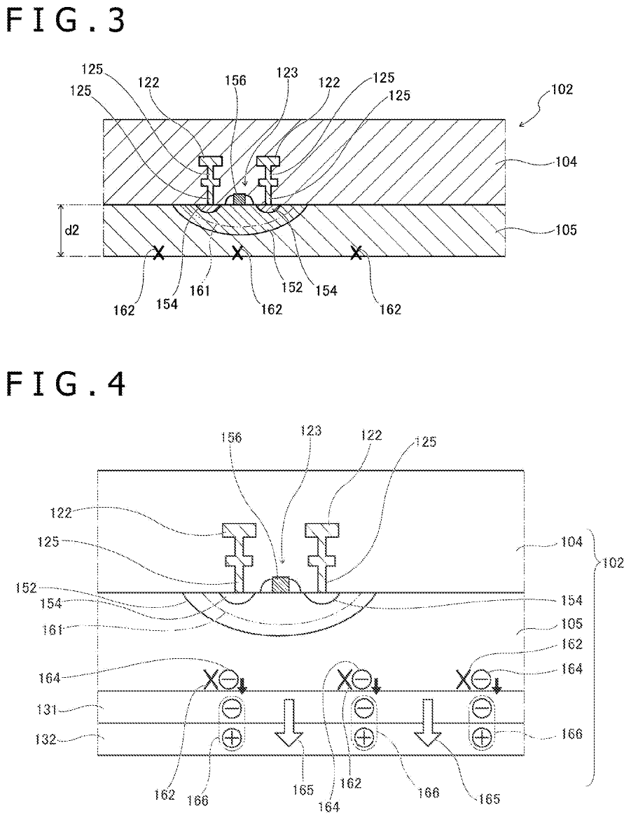

FIG. 3 is a view illustrating an example in which the lower surface of the logic chip 102 is polished to be much thinner than the example illustrated in FIG. 2. Specifically, the logic chip 102 is formed such that its film thickness becomes d2 that is much thinner than d1 by polishing, as illustrated in FIG. 3, in order to achieve a low height.

As illustrated in FIG. 3, when the film thickness of the silicon substrate 105 is formed to be thin at d2, for example, the distance between the N well 152 of the P-type transistor 123 disposed on the upper surface of the silicon substrate 105 and the defect 162 becomes small. Hence, the depletion layer 161 of the transistor 123 may reach the defect 162. When the depletion layer 161 reaches the defect 162, since the electron 164 is present in the defect 162, the electron 164 enters the depletion layer 161, and leakage occurs therefrom, which is problematic.

FIG. 4 is a diagram of assistance in explaining a principle allowing occurrence of leakage to be prevented by stacking two films, such as the oxide film 131 that is a first insulating film and the charged film 132 that is a second insulating film, on the polished surface of the lower surface of the silicon substrate 105. The oxide film 131 as the first insulating film includes an insulator having oxygen atoms such as silicon dioxide (SiO₂), for example. The charged film 132 as the second insulating film includes an insulator with a large dielectric constant κ (referred to as ϵ in electrical engineering), which is called a High-k dielectric, for example. Silicon dioxide includes two oxygen atoms per molecule, as understood from a chemical formula. In addition, the High-k dielectric is an oxide and differs in quantity of oxygen atoms, depending on a material.

Accordingly, when a certain High-k dielectric is stacked on the silicon dioxide, polarization occurs in both films due to a difference in oxygen surface density. Specifically, a force of oxygen for moving from an insulator with a larger oxygen surface density to an insulator with a smaller oxygen surface density acts. However, silicon dioxide and the High-k dielectric are insulators (dielectrics), and accordingly, movement of the electrons 164 and the holes 163 are restricted, so that they are not able to freely move in the insulators. Owing to this, according to the difference in oxygen surface density of both of the insulators, migration (displacement) of negative charges occurs, and a dipole 166 is generated, as illustrated in FIG. 4. Accordingly, for example, it is conceivable that the oxide film 131 including silicon dioxide and the charged film 132 including the High-k dielectric generate polarization. Note that, although FIG. 4 illustrates a case of the electron 164, in the case of the hole 163 in FIG. 4, the electron 164 is assumed to be replaced by the hole 163 (in FIG. 4, “−” in the circle is replaced by “+” in the circle). In addition, in FIG. 4, a polarity of the dipole 166 and an orientation of an internal electric field 165 are assumed to be reversed.

A magnitude of polarization varies depending on an oxygen surface density of each of silicon dioxide and the High-k dielectric. Owing to this, the charged film 132 including the High-k dielectric with a predetermined oxygen surface density is stacked on the oxide film 131, positive or negative charges appear in the charged film 132 and the oxide film 131, according to the difference in oxygen surface density between both of the films.

For example, the charged film 132 including the High-k dielectric with a lower oxygen surface density than that of silicon dioxide is stacked on the oxide film 131 including silicon dioxide, as illustrated in FIG. 4, oxygen migrates to the charged film 132, so that polarization in which the oxide film 131 becomes positive and the charged film 132 becomes negative occurs. This is referred to as a positive charged film. Conversely, the charged film 132 including the High-k dielectric with a higher oxygen surface density than that of silicon dioxide is stacked on the oxide film 131, the oxygen migrates to the oxide film 131, so that polarization in which the oxide film 131 becomes negative and the charged film 132 becomes positive occurs. This is referred to as a negative charged film. Note that, since it is only required if the oxide film 131 is an insulator having oxygen atoms, such as silicon dioxide, the oxide film 131 may be a BOX layer including an oxide film to be described later.

FIG. 4 illustrates an example in which the oxygen surface density of silicon dioxide forming the oxide film 131 stacked on the lower surface serving as the polished surface of the silicon substrate 105 is lower than the oxygen surface density of the High-k dielectric forming the charged film 132. In this case, the dipole 166 has the oxide film 131 side as a negative and the charged film 132 side as a positive. Here, an orientation of the internal electric field 165 generated in the oxide film 131 and the charged film 132 due to polarization is indicated with an arrow. The orientation of the internal electric field 165 in the insulator (dielectric) becomes a direction from the negative charges to the positive charge.

Accordingly, an orientation of an electric field outside the oxide film 131 also becomes an opposite direction to that of the internal electric field 165. Owing to this, the positive charges are induced at the upper surface (front surface) of the oxide film 131 and for example, recombined with the electrons 164 caught in the defects or may be less likely to be caught in the defects 162.

In the example of FIG. 4, the electrons 164 are present in the defects 162 generated in the polished surface. Here, the orientation of the internal electric field 165 in the oxide film 131 and the charged film 132 is a direction from the oxide film 131 to the charged film 132, and accordingly, the electrons 164 cannot be present in the defects 162. As a result, since the electrons 164 are not caught in the defects 162 present in the depletion layer 161, a leakage path attributable to the electron 164 is not formed between the N well 152 and another N well adjacent thereto. That is, it is possible to prevent the leakage.

In the example of FIG. 4, a case in which the transistor 123 is the P type has been described, but it is not limited to the P type, and may be the N type. In addition, in a case in which the hole 163 is present in the defect 162 generated in the polished surface, it is sufficient that the High-k dielectric polarized such that the oxide film 131 side thereof is positive and the charged film 132 side is negative may be used as the charged film.

As such, in a case in which a positive charged film is formed, the orientation of the internal electric field 165 due to the polarization becomes an opposite direction relative to the direction indicated in FIG. 4, and the hole 163 that is a positive charge is drawn to the upper surface (front surface) of the oxide film 131. As a result, the hole 163 that is present in the defect 162 does not move in a direction in which a P well 151 is present and is drawn to the oxide film 131, to be caught at the upper surface (front surface) of the oxide film 131. Hence, leakage from the depletion layer 161 can be prevented.

The charged film 132 including a High-k dielectric serving as the second insulating film can include, for example, hafnium oxide (HfO₂), aluminum oxide (Al₂O₃), zirconium oxide (ZrO₂), tantalum pentoxide (Ta₂O₅), titanium oxide (TiO₂), lanthanum oxide (La₂O₃), or yttrium oxide (Y₂O₃). Specifically, the charged film 132 is, for example, a film formed by at least any one material selected from these materials.

In these High-k dielectrics, for example, hafnium oxide and aluminum oxide are larger in oxygen surface density than silicon dioxide forming the oxide film 131. Accordingly, when these materials are used for the charged film 132, the charged film 132 side is positively polarized, and the oxide film 131 side is negatively polarized. Hence, these High-k dielectrics become the negative charged film 132.

In addition, for example, lanthanum oxide and yttrium oxide are smaller in oxygen surface density than silicon dioxide forming the oxide film 131, and accordingly, when these materials are used for the charged film 132, the charged film 132 side is negatively polarized, the oxide film 131 side is positively polarized. Hence, these High-k dielectrics become a positive charged film.

### (Application Example of Present Embodiment and Effect)

As is described above, the oxide film 131 and the charged film 132 are stacked on the lower surface (polished surface) of the silicon substrate 105, so that the electron 164 or the hole 163 that is present in the defect 162 attributable to polishing or contamination can be caught in the oxide film 131, thereby allowing the silicon substrate 105 to be thinned without generating leakage.

In addition, as illustrated in FIG. 1, the present embodiment is an example in which two chips such as the logic chip 102-1 in which the oxide film 131 and the charged film 132 are stacked on the lower surface (polished surface) of the silicon substrate 105-1 and the logic chip 102-2 in which the oxide film 131 and the charged film 132 are not stacked are bonded to one CIS chip 101 by Cu—Cu bonding. Such a structure is suitable to CoW. Specifically, on the CIS chip 101 in a wafer-like shape, the logic chips 102-1 and 102-2 which are manufactured in other steps can be formed in a face-to-face (F2F) manner by Cu—Cu bonding.

As a result, it is possible to bond the two logic chips 102-1 and 102-2 to the one CIS chip 101. In addition, the logic chip 102-1 has the oxide film 131 and the charged film 132 stacked thereon, and the logic chip 102-2 may not have them stacked thereon. Consequently, in a case in which both the logic chips 102-1 and 102-2 are different in thickness, the logic chip 102 having a greater thickness is polished, and it is possible to bond the two logic chips 102-1 and 102-2 to the one CIS chip 101 in a state in which the thicknesses of both of the films are made to be uniform by stacking the oxide film 131 and the charged film 132 on the polished surface.

Thus, it is permissible that the logic chip 102-1 having the oxide film 131 and the charged film 132 stacked thereon and the logic chip 102-2 having no films stacked thereon may be present in a mixed manner.

In addition, the logic chip may be only the logic chip 102-1 having the oxide film 131 and the charged film 132 stacked thereon. Alternatively, multiple number of logic chips 102-1 and 102-2 may be present in a mixed manner.

As described above, according to the present embodiment, the oxide film 131 including silicon dioxide and the charged film 132 including the High-k dielectric are stacked on the polished surface of the silicon substrate 105. Consequently, it is possible to prevent occurrence of leakage caused by the electron 164 or the hole 163 entering the depletion layer 161, the electron 164 or the hole 163 being present in the defect 162 generated in the vicinity of the polished surface due to polishing or contamination. Further, it is possible to achieve reduction in film thickness of the silicon substrate 105, reduction in height and size of the solid-state imaging device 10, and higher integration of the solid-state imaging device 10.

### 2. Basic Form of Second Embodiment of Solid-State Imaging Device According to Present Disclosure

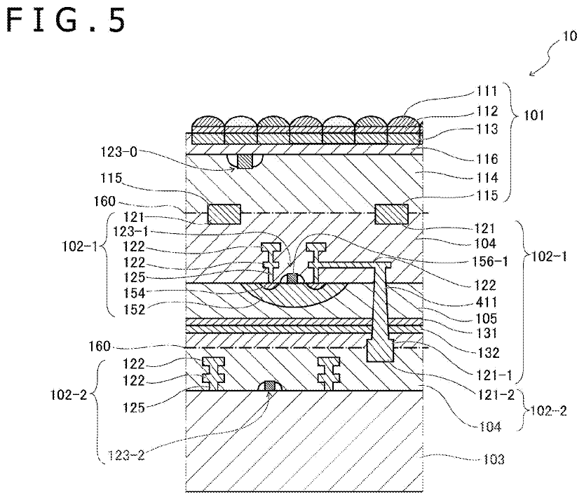

Next, with reference to FIG. 5, a basic form of a second embodiment of the solid-state imaging device 10 according to the present disclosure will be described. The basic form of the second embodiment is a configuration obtained by stacking semiconductor chips in three layers and is, for example, applicable to wafer on wafer on wafer (hereinafter referred to as “WoWOW”).

FIG. 5 is a cross-sectional view illustrating a schematic structure of the basic form of the second embodiment of solid-state imaging device 10 according to the present disclosure. As illustrated in FIG. 5, the solid-state imaging device 10 has the logic chip 102-2 stacked on the support substrate 103, has the logic chip 102-1 stacked on the logic chip 102-2, and has the CIS chip 101 stacked on the logic chip 102-1. In FIG. 5, an upper side is a light incidence surface side. Hence, the CIS chip 101 is stacked on the light incidence surface side.

As illustrated in FIG. 5, for example, the CIS chip 101 has a configuration similar to that of the first embodiment described in FIG. 1. Accordingly, description thereof will be omitted.

On the support substrate 103, as illustrated in FIG. 5, the logic chip 102-2 is disposed. The logic chip 102-2 has the logic circuits formed in the multilayer wiring layer 104 on the support substrate 103. More specifically, the transistor 123-2 is disposed on the support substrate 103. Also, above the transistor 123-2, the multilayer wiring layer 104 is disposed, and each wiring layer thereof has the wire 122 formed therein, the wire 122 including the circuits such as any of the vertical drive section, the horizontal drive section, and the like which are described above. In addition, the upper and lower sides of the wires 122 are connected through the vias 125 in the up-down direction (the vertical direction in FIG. 5).

The logic chip 102-1 has the logic circuits formed in the multilayer wiring layer 104 on the silicon substrate 105. Specifically, on the silicon substrate 105, the transistor 123-1 is disposed. Also, above the transistor 123-1, the multilayer wiring layer 104 is disposed, and each wiring layer thereof has the wire 122 formed therein, the wire 122 including the rest of the circuits such as any of the vertical drive section, the horizontal drive section, and the like which are described above. In addition, the upper and lower sides of the wires 122 are connected through the vias 125 in the up-down direction (the vertical direction in FIG. 5).

The transistor 123-1 in FIG. 5 is a P-type transistor, and the P+ diffusion layers 154 forming the drain and the source are disposed across a gate 156-1. Also, the N well 152 is formed in the periphery of the P+ diffusion layers 154.

The oxide film 131 is stacked on the lower surface of the silicon substrate 105, and further, the charged film 132 is stacked on the lower surface of the oxide film 131. Since actions of the oxide film 131 and the charged film 132 are similar to those in the first embodiment, description thereof will be omitted. Note that the transistors 123-0 and 123-2 also have the P+ diffusion layers 154 and the N well 152 as in the first embodiment, and illustration and description thereof will be omitted for simplification. In the following, the same applies to the similar cases.

The logic chip 102-1 and the CIS chip 101 are bonded to each other by Cu—Cu bonding in a face-to-face manner. The logic chip 102-1 and the CIS chip 101 have respective pads 121 and 115 necessary for Cu—Cu bonding formed therein. Description of the Cu—Cu bonding between the logic chip 102 and the CIS chip 101 will be omitted since it is similar to that in the first embodiment.

The logic chip 102-1 and the logic chip 102-2 are connected in a back-to-face (B2F) manner. Specifically, since the upper surface of the logic chip 102-1 is bonded to the CIS chip 101, the lower surface of the logic chip 102-1 is required to be connected to the logic chip 102-2.

More specifically, below the multilayer wiring layer 104 in which the circuits of the logic chip 102-1 are formed, the silicon substrate 105 is present. Owing to this configuration, the logic chip 102-1 and the 102-2 are not able to be connected to each other by Cu—Cu bonding. In view of this, the silicon substrate 105, the charged film 132, and the oxide film 131 have a TSV 411 formed therethrough. The TSV 411 connects the wire 122 constituting the circuits of the logic chip 102-2 with the wire 122 constituting the circuits of the logic chip 102-1 on the upper side thereof.

As such, in the lower surface of the silicon substrate 105, that is, in the surface on which the oxide film 131 and the charged film 132 are stacked, a lower end of the TSV 411 is opened. This opening has a pad 121-1 formed therein. Meanwhile, in the upper surface of the logic chip 102-2, a pad 121-2 is formed at a position corresponding to the opening of the TSV 411 in such a manner as to face the pad 121-1.

Accordingly, the pads 121-1 and 121-2 formed in the respective logic chips 102-1 and 102-2 are opposed to each other, thereby achieving Cu—Cu bonding therebetween at the bonding surface 160.

As described above, the oxide film 131 including silicon dioxide and the charged film 132 including the High-k dielectric are stacked on the polished surface serving as the lower surface of the silicon substrate 105. With this configuration, the electron 164 or the hole 163 that is present in the defect 162 generated in the vicinity of the polished surface due to polishing or contamination is drawn to the front surface of the oxide film 131. Consequently, occurrence of leakage caused by the electron 164 or the hole 163 entering the depletion layer 161 can be eliminated. Moreover, not only thinning of the silicon substrate 105, but also reduction in height of the solid-state imaging device 10 can be achieved.

In addition, since such a three-layered configuration described above makes it possible to perform Cu—Cu bonding between the individual chips, bonding of three wafers with one another is enabled. In particular, the logic chips 102-1 and 102-2 can be formed with a reduced thickness, allowing the height of the TSV to be small, so that the diameter of the TSV can be made small in association with the reduced height of the TSV. In addition, this enables an increased effective area of the chip, so that reduction in height and size of the solid-state imaging device 10 and higher integration thereof can be achieved.

### 3. First Modification Example of Second Embodiment of Solid-State Imaging Device According to Present Disclosure

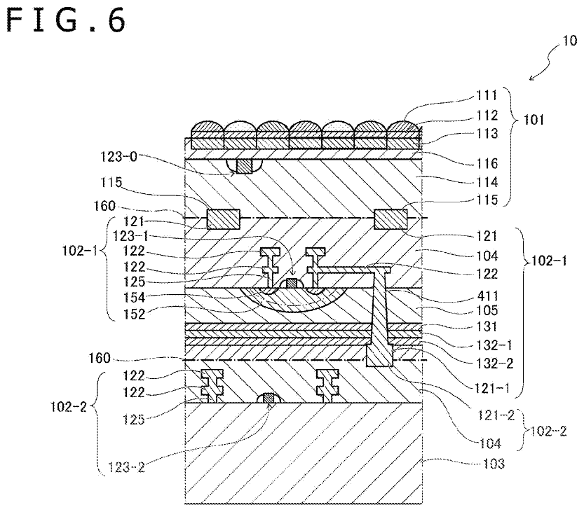

Next, with reference to FIG. 6, a first modification example of the second embodiment of the solid-state imaging device 10 according to the present disclosure will be described. The first modification example according to the second embodiment adopts a configuration in which chips are stacked in three layers, as in the basic form, for example, and it is applicable to WoWoW.

The present first modification example and the basic form of the second embodiment differ from each other in that, while the negative charged film 132 and the oxide film 131 are stacked in one layer each in the basic form, for example, two charged films 132-1 and 132-2 having the same type of polarity, positive or negative, are stacked as illustrated in FIG. 6, in the present first modification example. Except for this, the present first modification example is similar to the basic form of the second embodiment, and description thereof will be omitted.

Stacking the two charged films 132-1 and 132-2 in the manner described above can further improve an effect of preventing occurrence of leakage caused by the defect 162 and the like generated in the polished surface.

### 4. Second Modification Example of Second Embodiment of Solid-State Imaging Device According to Present Disclosure

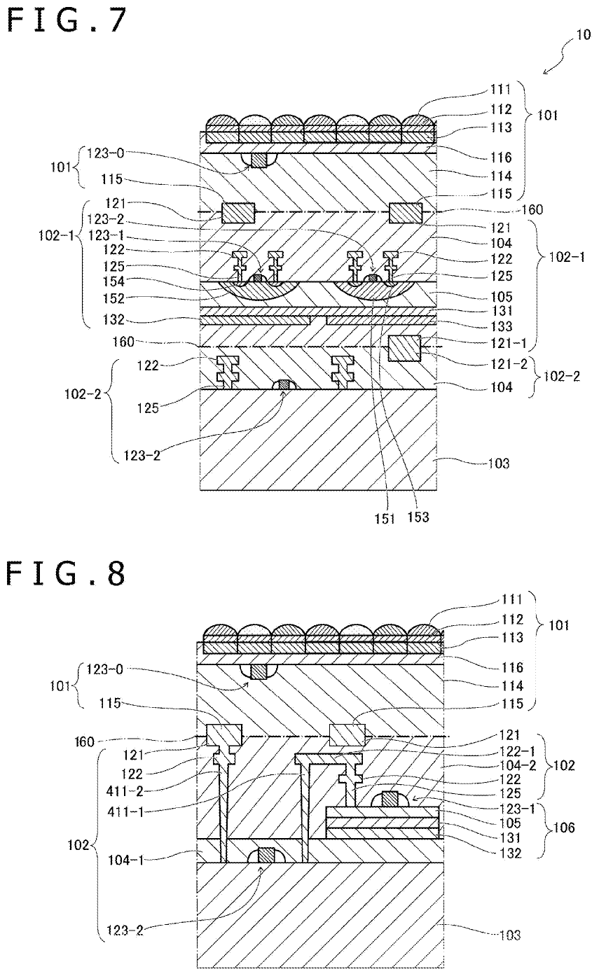

Next, with reference to FIG. 7, a second modification example of the second embodiment of the solid-state imaging device 10 according to the present disclosure will be described. The second modification example of the second embodiment adopts a configuration in which chips are stacked in three layers, as in the basic form, for example, and it is applicable to WoWoW.

The present second modification example and the basic form of the second embodiment differ from each other in that, while one type of the charged film 132 is stacked on the oxide film 131 in the basis form, two types of charged films, the negative charged film 132 and a positive charged film 133, are stacked on the oxide film 131 such that respective stacked regions of the negative charged film 132 and the positive charged film 133 are separated from each other in the present second modification example, as illustrated in FIG. 7. In this case, the charged film 132 and the charged film 133 are formed to be positive or negative, depending on a difference in oxygen surface density.

In addition, the transistor 123-1 is a P-type transistor, and the transistor 123-2 is an N-type transistor. Also, stacking the charged film 132 on the oxide film 131 on the lower surface of the transistor 123-1 forms the negative charged film 132. In addition, stacking the charged film 133 on the oxide film 131 on the lower surface of the transistor 123-2 forms the positive charged film 133.

According to the modification example of the present embodiment, the charged films 132 and 133 having different polarities can be mixed in one semiconductor chip, different types of semiconductor elements can be integrated in one semiconductor chip, thereby achieving a higher integration degree.

The configurations other than those described above are similar to those in the basic form of the second embodiment, and accordingly, description thereof will be omitted.

### 5. Third Embodiment of Solid-State Imaging Device According to Present Disclosure

Next, with reference to FIG. 8, a third embodiment of the solid-state imaging device 10 according to the present disclosure will be described. The third embodiment is configured such that, for example, a semiconductor chip (hereinafter, referred to as a “monolithic chip”) 106 with a monolithic structure having a semiconductor active element such as a transistor is incorporated in the logic chip 102, and it can be applied to, for example, CoW or WoW.

The solid-state imaging device 10 according to the present third embodiment has the logic chip 102 stacked on the support substrate 103, and the logic chip 102 has the monolithic chip 106 incorporated therein, as illustrated in FIG. 8. In addition, the CIS chip 101 is bonded onto the logic chip 102 by Cu—Cu bonding at the bonding surface 160. In FIG. 8, as in the first embodiment, the upper side of the figure is the light incidence surface side. Hence, the CIS chip 101 is stacked on the light incidence surface side.

As illustrated in FIG. 8, the monolithic chip 106 incorporated in the logic chip 102 has the transistor 123-1 disposed therein on the silicon substrate 105. In addition, the oxide film 131 and the charged film 132 are stacked on the lower surface of the silicon substrate 105 in the monolithic chip 106. In addition, above the monolithic chip 106, a multilayer wiring layer 104-2 and the wire 122 of the logic chip 102 are formed and are connected through the via 125 in the up-down direction.

The logic chip 102 has the transistor 123-2 disposed therein and has circuits formed therein. In this case, the circuits of the transistor 123-1 on the monolithic chip 106 and the circuits of the transistor 123-2 in the logic chip 102 are connected to each other through the via 125, the wire 122-1, and the TSV 411-1.

The logic chip 102 and the CIS chip 101 have respective pads 121 and 115 necessary for performing Cu—Cu bonding formed therein, as in the first embodiment. The logic chip 102 and the CIS chip 101 are connected to each other in a face-to-face manner through Cu—Cu bonding of the pads 121 and 115. Thus, the circuits of the transistor 123-2 are connected to the pad 121 through the TSV 411-2.

With this configuration, it is possible to reduce the monolithic chip 106 in its film thickness to be incorporated in the logic chip 102.

As described above, the oxide film 131 including silicon dioxide or the like and the charged film 132 including the High-k dielectric are stacked on the lower surface (polished surface) of the silicon substrate 105. This configuration makes it possible to prevent occurrence of leakage at the depletion layer 161. In addition, reduction in film thickness of the silicon substrate 105 resulting from reduction in film thickness of the monolithic chip 106 can achieve reduction in height of the solid-state imaging device 10 and a higher integration thereof.

In addition, since the monolithic chip 106 can be incorporated in the logic chip 102 and Cu—Cu bonding can be made between the CIS chip 101 and the logic chip 102, thereby allowing implementation of CoW or WoW. Hence, reduction in height and size of the solid-state imaging device 10 and a higher integration thereof can be achieved.

### 6. Fourth Embodiment of Solid-State Imaging Device of Present Disclosure

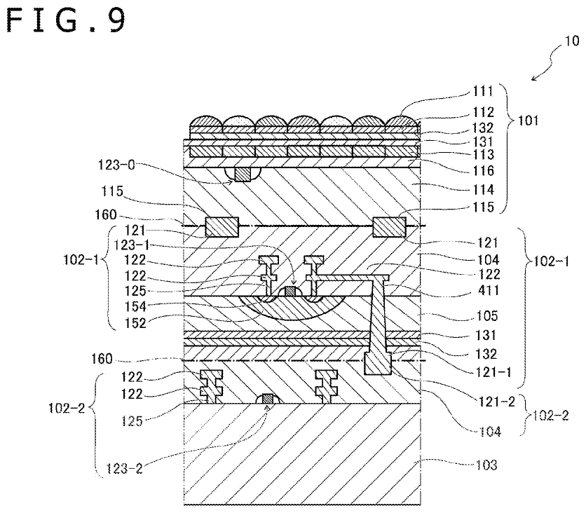

Next, with reference to FIG. 9, a fourth embodiment of the solid-state imaging device 10 of the present disclosure will be described. The present embodiment is configured such that, for example, the oxide film 131 and the negative charged film 132 or the positive charged film 133 are stacked between the color filter 112 and the photodiode 113 on the light incidence surface side of the CIS chip 101. FIG. 9 illustrates an example in which the negative charged film 132 is stacked on the oxide film 131.

On the light incidence surface side of the CSI chip 101, as described in the first embodiment, in order to form the photodiode 113 after the photodiode formation layer 116 is formed to be thin by polishing, the defect 162 is generated in the vicinity of the polished surface due to polishing or contamination. Owing to this, the electron 164 or the hole 163 that is present in the defect 162 enters the depletion layer 161 of the transistor 123-0, possibly causing occurrence of leakage.

In view of this, as illustrated in FIG. 9, stacking the oxide film 131 and the negative charged film 132 or the positive charged film 133 on the polished surface that is the light incidence surface side of the CSI chip 101 makes it possible to prevent leakage. Note that, since the oxide film 131 and the charged film 132 are formed to be thin, they will not be hindrance to light reception of the photodiode 113.

According to the configuration of the present embodiment described above, the photodiode formation layer 116 can be reduced in its film thickness, and occurrence of leakage can be prevented. Accordingly, the solid-state imaging device 10 can be operated stably, thereby realizing high quality of the solid-state imaging device 10.

### 7. Fifth Embodiment of Solid-State Imaging Device According to Present Disclosure

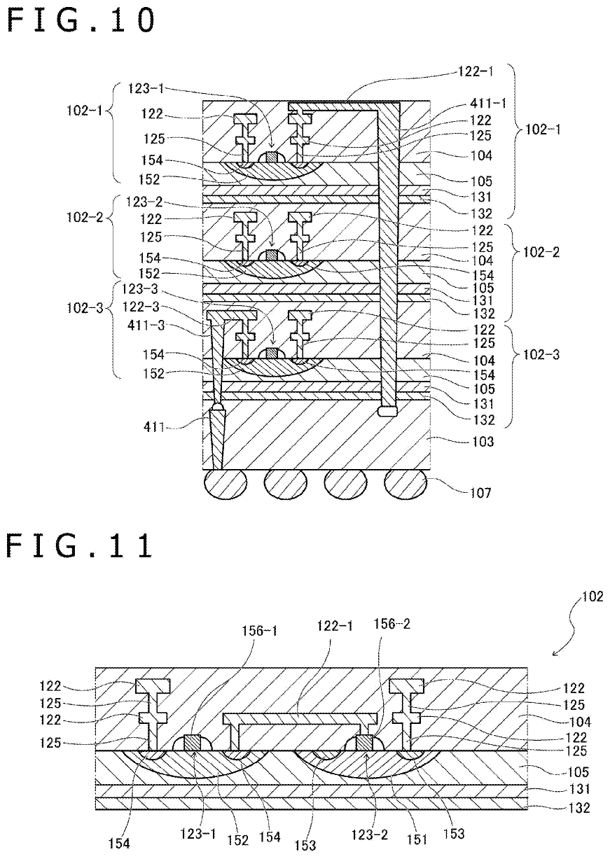

Next, with reference to FIG. 10, a fifth embodiment of the solid-state imaging device 10 according to the present disclosure will be described. The fifth embodiment is configured such that, for example, the logic chip 102 and the like to be used in the solid-state imaging device 10 or the like are stacked in multiple layers.

As illustrated in FIG. 10, the logic chip 102 of the solid-state imaging device 10 according to the present embodiment is configured such that three semiconductor chips, the logic chips 102-1 and 102-2 and 102-3, are stacked on the support substrate 103.

More specifically, as illustrated in FIG. 10, the logic chip 102-3 is disposed on the support substrate 103. The oxide film 131 and the charged film 132 are stacked on the lower surface of the silicon substrate 105 of the logic chip 102-3. In addition, the transistor 123-3 that is a semiconductor active element is disposed on the silicon substrate 105 of the logic chip 102-3. In addition, the multilayer wiring layer 104 having the interlayer insulating film formed therein is disposed above the transistor 123-3, and each wiring layer has the wire 122 constituting a predetermined circuit formed therein. In addition, the upper and lower sides of the wires 122 are connected through the vias 125 in the up-down direction (the vertical direction in FIG. 10).

As illustrated in FIG. 10, the logic chip 102-2 is disposed on the logic chip 102-3. The oxide film 131 and the charged film 132 are stacked on the lower surface of the logic chip 102-2. In addition, the transistor 123-2 is disposed on the silicon substrate 105 of the logic chip 102-2. Configurations of wires and the like of the transistor 123-2 are similar to those of the logic chip 102-3, and description thereof will be omitted.

As illustrated in FIG. 10, the logic chip 102-1 is disposed on the logic chip 102-2. The oxide film 131 and the charged film 132 are stacked on the lower surface of the logic chip 102-1. In addition, the transistor 123-1 is disposed on the silicon substrate 105 of the logic chip 102-1. Configurations of wires and the like of the transistor 123-1 are similar to those of the logic chip 102-3, and description thereof will be omitted.

Next, the wires between the chips will be described. As illustrated in FIG. 10, the transistor 123-3 of the logic chip 102-3 is connected with the support substrate 103 through the via 125, the wire 122-3, and the TSV 411-3. In the support substrate 103, the TSV 411-3 is connected with a solder ball 107 through the TSV 411, and the solder ball 107 is connected with an external circuit by being soldered on a printed board (not illustrated) in electronic equipment or the like in which the present solid-state imaging device 10 is incorporated.

The transistor 123-1 of the logic chip 102-1 is connected with the support substrate 103 through the via 125, the wire 122-1, and the TSV 411-1. The TSV 411-1 may further be connected with the solder ball 107 through the TSV (not illustrated) in the support substrate 103.

The transistor 123-2 of the logic chip 102-2 is connected with a wire 122-2 through the via 125. Although illustration is not provided in FIG. 10, the transistor 123-2 may be connected with the logic chip 102-1, the logic chip 102-3, or the support substrate 103, through the TSV.

As described above, the oxide film 131 including silicon dioxide or the like and the charged film 132 including the High-k dielectric are stacked on the lower surface (polished surface) of each of the silicon substrates 105-1, 105-2, and 105-3. Accordingly, it is possible to prevent occurrence of leakage at the depletion layer 161 of each of the transistors 123-1, 123-2, and 123-3. Moreover, since the silicon substrate 105 can be reduced in film thickness, the logic chips 102-1, 102-2, and 102-3 can be reduced in film thickness. Hence, reduction in height and size of the solid-state imaging device 10 and higher integration thereof can be achieved.

In addition, the present embodiment can be used as the logic chip 102 of the solid-state imaging device 10 as a matter of course and is not limited to the solid-state imaging device 10. For example, stacking a plurality of semiconductor chips having other functions in multiple layers onto the logic chip 102 according to the present embodiment makes it possible to form a semiconductor device with high integration for other usages. Since the logic chip 102 according to the present embodiment in this manner has rich versatility, it is applicable to a semiconductor element other than the solid-state imaging device 10, the semiconductor element being used for every types of electronic equipment or industrial equipment.

### 8. Sixth Embodiment of Solid-State Imaging Device According to Present Disclosure

Next, with reference to FIG. 11, a sixth embodiment of a solid-state imaging device 10 according to the present disclosure will be described. The sixth embodiment relates to, for example, a single-layer device such as the logic chip 102.

The solid-state imaging device 10 according to the present embodiment includes the logic chip 102 illustrated in FIG. 11.

More specifically, as illustrated in FIG. 11, the logic chip 102 has transistors 123-1 and 123-2 disposed on the silicon substrate 105. The transistor 123-1 is a P-type transistor, and a drain and a source thereof have P+ diffusion layers 154 formed therein. Of these P+ diffusion layers 154, the left P+ diffusion layer 154 is connected to each circuit through the via 125 and the wire 122, and the right P+ diffusion layer 154 is connected to a gate 156-2 of the transistor 123-2. In addition, the N well 152 is formed on the periphery of the P+ diffusion layers 154 in the silicon substrate 105.

The transistor 123-2 is an N-type transistor, and a drain and a source thereof have N+ diffusion layers 153 formed therein. Of these N+diffusion layers 153, the right N+ diffusion layer 153 is connected to each circuit through the via 125 and the wire 122. In addition, the P well 151 is formed on the periphery of the N+ diffusion layers 153 in the silicon substrate 105.

In addition, above the transistors 123-1 and 123-2, the multilayer wiring layer 104 is disposed. Each wiring layer of the multilayer wiring layer 104 has the wire 122 constituting a predetermined circuit formed therein, and the upper and lower sides of the wires 122 are connected through the vias 125 in the up-down direction (the vertical direction in FIG. 11).

Also, the oxide film 131 is stacked on the lower surface (polished surface) of the silicon substrate 105 on which the P-type transistor 123-1 and the N-type transistor 123-2 are disposed, and the charged film 132 is further stacked on the oxide film 131. Note that, as described in FIG. 7, the negative charged film 132 may be stacked on the lower surface of the P-type transistor 123-1, and the positive charged film 133 may be stacked on the lower surface of the N-type transistor 123-2.

As described above, the oxide film 131 including silicon dioxide or the like and the negative charged film 132 including the High-k dielectric or the positive charged film 133 are stacked on the lower surface (polished surface) of the silicon substrate 105. Hence, it is possible to prevent occurrence of leakage at the depletion layer 161 of the P-type transistor 123-1 or the N-type transistor 123-2. Moreover, reduction of the film thickness of the silicon substrate 105 enables the logic chip 102 to be reduced in film thickness. As a result of this, reduction in height and size of the solid-state imaging device 10 and higher integration thereof can be achieved.

In addition, the logic chip 102 according to the present embodiment is used as the logic chip 102 of the solid-state imaging device 10 as a matter of course and is not limited to the solid-state imaging device 10. For example, stacking a plurality of semiconductor chips having other functions in multiple layers onto the logic chip 102 according to the present embodiment makes it possible to form a semiconductor device with high integration for other usages. Since the logic chip 102 according to the present embodiment in this manner has rich versatility, it is applicable to a semiconductor element other than the solid-state imaging device 10, the semiconductor element being used for every types of electronic equipment or industrial equipment.

### 9. Method of Manufacturing Solid-State Imaging Device According to Present Disclosure

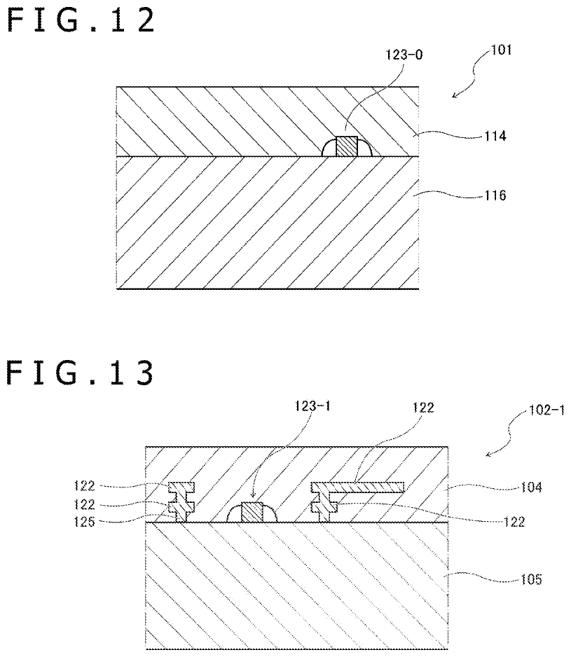

Next, a method of manufacturing the solid-state imaging device 10 according to the present disclosure will be described, taking as an example the basic form of the second embodiment of the first to the sixth embodiments, with reference to FIG. 12 to FIG. 19.

First, as illustrated in FIG. 12, the CIS chip 101 is prepared. The CIS chip 101 has a photodiode formation layer 116 for forming the photodiodes 113, a wiring layer 114, and the like preliminarily formed therein, for example, and has the transistor 123-0 disposed therein.

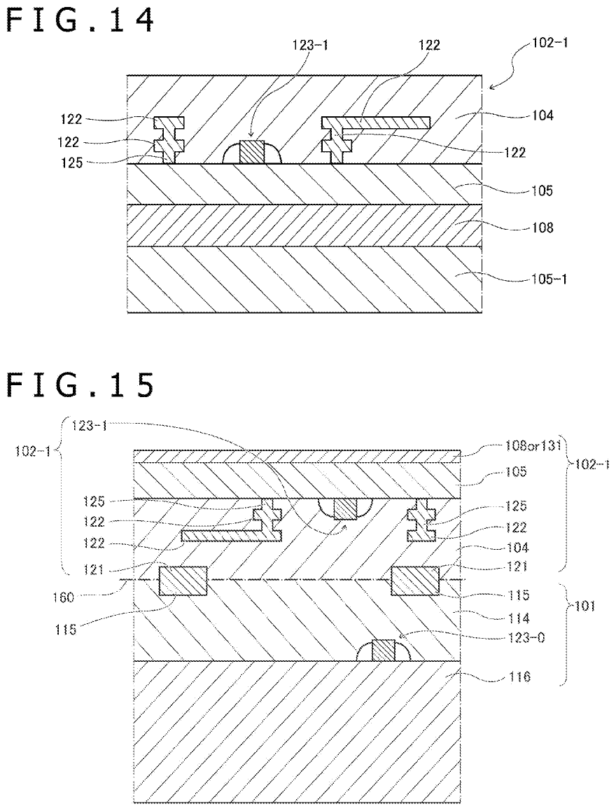

In addition, concurrently with this, as illustrated in FIG. 13, the logic chip 102-1 is prepared. The logic chip 102-1 is substantially similar to that described in FIG. 5, and accordingly, description thereof will be omitted. Alternatively, in place of the logic chip 102-1, as illustrated in FIG. 14, a logic chip 102-1 in which a buried oxide film (BOX: Buried Oxide, referred to as a “BOX layer”) 108 is buried may be applicable.

The BOX layer 108 is an insulator that separates the active element region (SOI: Silicon on Insulator) such as the transistor 123. For example, as illustrated in FIG. 14, formation of the BOX layer 108 below the transistor 123-1 separates and insulates the silicon substrate 105 that becomes a region where the depletion layer 161 is to be generated from the silicon substrate 105-1. Hence, the depletion layer 161 can be confined in the silicon substrate 105.

In this case, a lower surface of the silicon chip 105-1 illustrated in FIG. 14 is polished to expose a lower surface of the BOX layer 108, so that part of the BOX layer 108 is caused to remain. This BOX layer 108 is, for example, a silicon dioxide insulating film, thereby functioning as the oxide film 131. Hence, in a case in which part of the BOX layer 108 is caused to remain, the charged film 132 may be stacked directly on the remaining part of the BOX layer 108, in place of the oxide film 131.

Next, the photodiode formation layer 116 of the CIS chip 101 illustrated in FIG. 12 is polished to be thin.

Similarly, the silicon substrate 105 of the logic chip 102-1 illustrated in FIG. 13 is polished to be thin.

Alternatively, in place of the logic chip 102-1, the lower surface of the silicon substrate 105-1 illustrated in FIG. 14 is polished to be removed, and further, the lower surface of the BOX layer 108 is polished, thereby causing part of the BOX layer 108 to remain.

Next, as illustrated in FIG. 15, the logic chip 102-1 illustrated in FIG. 13 or the logic chip 102-1 having the BOX layer 108 illustrated in FIG. 14 are rotated by 180° in the up-down direction, to be bonded onto the CIS chip 101.

As for bonding, the pads 115 and 121 are formed in advance in the CIS chip 101 and the logic chip 102-1 or the logic chip 102-1 having the BOX layer 108, respectively, and the corresponding pads 115 and 121 are connected with each other by Cu—Cu bonding at the bonding surface 160.

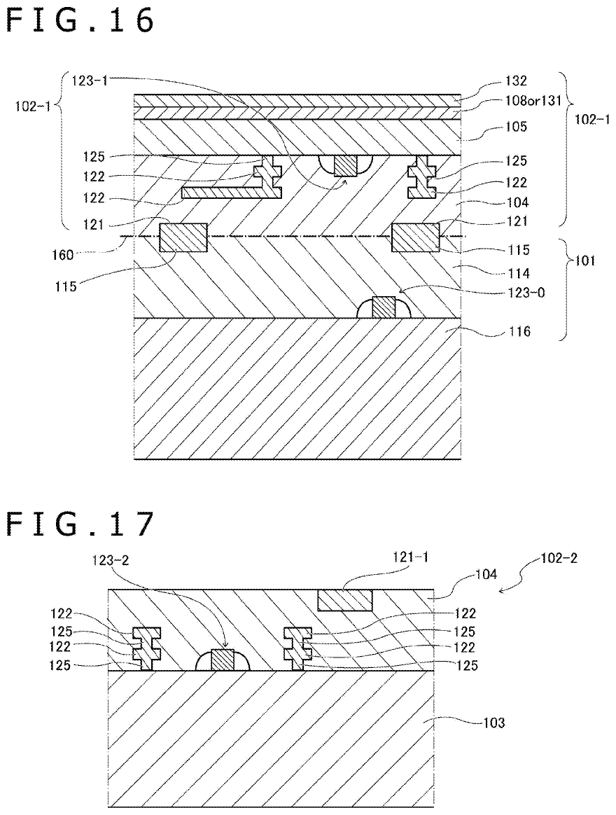

Next, as illustrated in FIG. 16, the oxide film 131 and the charged film 132 are stacked on the polished surface of the silicon substrate 105 of the logic chip 102-1 illustrated in FIG. 13. Alternatively, in a case in which the part of the BOX layer 108 illustrated in FIG. 14 is caused to remain, in place of the oxide film 131, the charged film 132 may be stacked directly on the polished surface of the BOX layer 108.

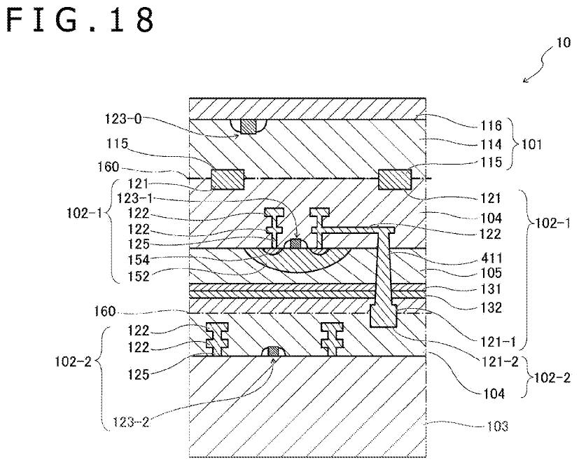

In addition, in another step, as illustrated in FIG. 17, the logic chip 102-2 formed on the support substrate 103 is prepared. This logic chip 102-2 is similar to that described in FIG. 5 as the basic form of the second embodiment, and accordingly, description thereof will be omitted.

Next, as illustrated in FIG. 18, a thin silicon layer is formed on the front surface of the charged film 132 of the logic chip 102-1 or the logic chip 102-1 having the BOX layer 108 which is connected with the CIS chip 101 by Cu—Cu bonding in FIG. 16. Then, the resultant is rotated by 180° in the up-down direction.

Next, the TSV 411 is formed so as to penetrate the thin silicon layer formed as described above, the charged film 132, the oxide film 131, and the silicon substrate 105 from the lower side of the logic chip 102-1, and an opening of the TSV 411 has the pad 121-1 formed therein. Then, the pad 121-1 formed in the opening of the TSV 411 and the pad 121-2 of the logic chip 102-2 prepared in FIG. 17 are caused to face each other, to be connected at the bonding surface 160 by Cu—Cu bonding.

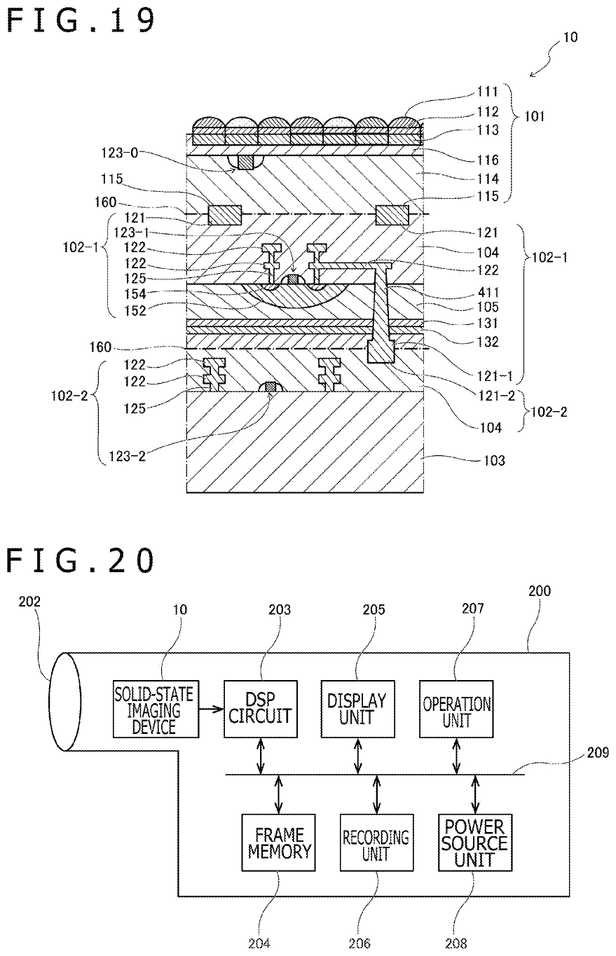

Next, as illustrated in FIG. 19, the photodiodes 113 are formed in the photodiode formation layer 116 of the CSI chip 101, which includes silicon. Then, the color filters 112 are correspondingly formed thereon, and further, the on-chip lenses 111 are correspondingly formed thereon.

Through the steps described above, the solid-state imaging device 10 can be manufactured.

Although the manufacturing process described above has been described taking the basic form of the second embodiment as an example, it is possible to manufacture the solid-state imaging device 10 also in another embodiment by adding some modifications to the manufacturing process of the present description.

### 10. Configuration Example of Electronic Equipment

An application example of the solid-state imaging device 10 according to the foregoing embodiments to electronic equipment will be described with reference to FIG. 20. Note that this application example is in common to the solid-state imaging device 10 according to the first embodiment to the sixth embodiment.

The solid-state imaging device 10 is applicable to electronic equipment in general using an image pickup unit (photoelectric conversion unit), such as an imaging device 200 like a digital still camera or a video camera, a portable terminal device having an imaging function, and a copying machine including the solid-state imaging device 10 as an image reading unit. The solid-state imaging device 10 may have a one-chip form or may be a packaged solid-state imaging device. Alternatively, the solid-state imaging device 10 may have a module-shaped form having an imaging function as a package collectively including an imaging unit and a signal processing unit or an optical system.

As depicted in FIG. 20, an imaging device 200 as electronic equipment includes an optical unit 202, the solid-state imaging device 10, a DSP (Digital Signal Processor) circuit 203 which is a camera signal processing circuit, a frame memory 204, a display unit 205, a recording unit 206, an operation unit 207, and a power source unit 208. The DSP circuit 203, the frame memory 204, the display unit 205, the recording unit 206, the operation unit 207, and the power source unit 208 are connected to one another via a bus line 209.

The optical unit 202 includes multiple lenses and captures incident light (image light) coming from a subject, to form an image of the incident light on an imaging plane of the solid-state imaging device 10. After the image of the incident light is formed on the imaging plane by the optical unit 202, the solid-state imaging device 10 converts light quantities of the incident light into electric signals for each pixel and outputs the electric signals as pixel signals.

For example, the display unit 205 includes a panel-type display device such as a liquid crystal panel and an organic EL (Electro Luminescence) panel and displays moving images or still images captured by the solid-state imaging device 10. The recording unit 206 records the moving images or the still images captured by the solid-state imaging device 10 in a recording medium such as a hard disk and a semiconductor memory.

The operation unit 207 issues operation commands associated with various functions of the imaging device 200 under operation by a user. The power source unit 208 appropriately supplies various types of power sources corresponding to operation power sources for the DSP circuit 203, the frame memory 204, the display unit 205, the recording unit 206, and the operation unit 207 to these supply targets.

According to the imaging device 200 described above, use of the solid-state imaging device 10 having a reduced thickness and with a size reduction can achieve reduction in size and weight of the imaging device 200. In addition, the higher integration can be improved, thereby allowing a captured image with a higher image quality to be obtained.

Besides, the above description of each embodiment is an example of the present disclosure, and the present disclosure is not limited to the above embodiments. Therefore, it goes without saying that various modifications can be made so as to implement an embodiment other than each of the above-described embodiments depending on the design and the like without departing from the technical idea according to the present disclosure. Further, the effects described in the present disclosure are merely illustrative and not restrictive, and other effects may also be achieved.

In addition, the present technique can also adopt the following configurations.

(1)

A solid-state imaging device including:
a first semiconductor chip including photodiodes;
a second semiconductor chip including a signal processing circuit from the photodiodes and which is stacked on the first semiconductor chip;
a first insulating film which is stacked on a second surface of the second semiconductor chip that is opposite to a first surface thereof having the first semiconductor chip stacked thereon and which includes oxygen; and
a second insulating film stacked on the first insulating film and including oxygen.
   (2)

The solid-state imaging device according to (1) above, in which
the second insulating film includes a High-k dielectric having an oxygen surface density different from the first insulating film.
   (3)

The solid-state imaging device according to (1) above or (2) above, in which
the second insulating film stacked on the first insulating film includes a negative insulating film or a positive insulating film.
   (4)

The solid-state imaging device according to any one of (1) above to (3) above, in which
a third insulating film including a High-k dielectric is stacked on the second insulating film.
   (5)

The solid-state imaging device according to any one of (1) above to (4) above, in which
the second insulating film includes hafnium oxide (HfO₂), aluminum oxide (Al₂O₃), zirconium oxide (ZrO₂), tantalum pentoxide (Ta₂O₅), titanium oxide (TiO₂), lanthanum oxide (La₂O₃), or yttrium oxide (Y₂O₃).
   (6)

The solid-state imaging device according to any one of (1) above to (5) above, in which
the second insulating film is stacked on a buried oxide film layer.
   (7)

The solid-state imaging device according to any one of (1) above to (6) above, including:
a third semiconductor chip having a semiconductor active element and in which the first insulating film and the second insulating film are stacked, in the first semiconductor chip or the second semiconductor chip.
   (8)

The solid-state imaging device according to any one of (1) above to (7) above, in which
two or more semiconductor chips are stacked on the first semiconductor chip.
   (9)

A solid-state imaging device including:
a semiconductor chip including photodiodes;
a first insulating film stacked on an upper surface of the photodiodes on a light incidence surface side of the semiconductor chip and including oxygen; and
a negative or a positive second insulating film stacked on the first insulating film and including oxygen.
   (10)

A semiconductor chip including:
a substrate having a polished surface;
a first insulating film formed on the polished surface and including oxygen;
a second insulating film stacked on the first insulating film and including oxygen; and
a semiconductor active element.
   (11)

The semiconductor chip according to (10) above, in which
a second semiconductor chip is bonded to a surface that is opposite to the polished surface.
   (12)

Electronic equipment including:
a solid-state imaging device including
   a first semiconductor chip including photodiodes,
   a second semiconductor chip including a signal processing circuit from the photodiodes and which is stacked on the first semiconductor chip,
   a first insulating film which is stacked on a second surface of the second semiconductor chip that is opposite to a first surface thereof having the first semiconductor chip stacked thereon and which includes oxygen, and
   a second insulating film stacked on the first insulating film and including oxygen; or
a semiconductor chip including
   a polished surface,
   a first insulating film stacked on the polished surface and including oxygen,
   a second insulating film stacked on the first insulating film and including oxygen, and
   a semiconductor active element.

### REFERENCE SIGNS LIST

10: Solid-state imaging device
101: CIS chip
102: Logic chip
103: Support substrate
104: Multilayer wiring layer
105: Silicon substrate
106: Monolithic chip
107: Solder ball
108: Buried oxide film (BOX layer)
109: Insulating film
111: On-chip lens
112: Color filter
113: Photodiode
114: Wiring layer
115: Pad
116: Photodiode formation layer
121: Pad
122: Wire
123: Transistor
125: Via
131: Oxide film
132: (Negative) charged film
133: (Positive) charged film
151: P well
152: N well
153: N+ diffusion layer
154: P+ diffusion layer
156: Gate
160: Bonding surface
161: Depletion layer
162: Defect
163: Hole
164: Electron
165: Internal electric field
166: Dipole
200: Imaging device
411: TSV

What is claimed is:

1. A solid-state imaging device, comprising:
a first semiconductor chip including photodiodes;
a second semiconductor chip including a signal processing circuit from the photodiodes and which is stacked on the first semiconductor chip;
a first insulating film which is stacked on a second surface of the second semiconductor chip that is opposite to a first surface thereof having the first semiconductor chip stacked thereon and which includes oxygen; and
a second insulating film stacked on the first insulating film and including oxygen.

2. The solid-state imaging device according to claim 1, wherein
the second insulating film includes a High-k dielectric having an oxygen surface density different from the first insulating film.

3. The solid-state imaging device according to claim 1, wherein
the second insulating film stacked on the first insulating film includes a negative insulating film or a positive insulating film.

4. The solid-state imaging device according to claim 1, wherein
a third insulating film including a High-k dielectric is stacked on the second insulating film.

5. The solid-state imaging device according to claim 1, wherein
the second insulating film includes hafnium oxide (HfO₂), aluminum oxide (Al₂O₃), zirconium oxide (ZrO₂), tantalum pentoxide (TazO₅), titanium oxide (TiO₂), lanthanum oxide (La₂O₃), or yttrium oxide (Y₂O₃).

6. The solid-state imaging device according to claim 1, wherein
the second insulating film is stacked on a buried oxide film layer.

7. The solid-state imaging device according to claim 1, comprising:
a third semiconductor chip having a semiconductor active element and in which the first insulating film and the second insulating film are stacked, in the first semiconductor chip or the second semiconductor chip.

8. The solid-state imaging device according to claim 1, wherein
two or more semiconductor chips are stacked on the first semiconductor chip.

9. A solid-state imaging device, comprising:
a semiconductor chip including photodiodes;
a first insulating film stacked on an upper surface of the photodiodes on a light incidence surface side of the semiconductor chip and including oxygen; and
a negative or a positive second insulating film stacked on the first insulating film and including oxygen.

10. A semiconductor chip, comprising:
a substrate having a polished surface;
a first insulating film formed on the polished surface and including oxygen;
a second insulating film stacked on the first insulating film and including oxygen; and
a semiconductor active element.

11. The semiconductor chip according to claim 10, wherein
a second semiconductor chip is bonded to a surface that is opposite to the polished surface.

12. Electronic equipment, comprising:
a solid-state imaging device including
a first semiconductor chip including photodiodes,
a second semiconductor chip including a signal processing circuit from the photodiodes and which is stacked on the first semiconductor chip,
a first insulating film which is stacked on a second surface of the second semiconductor chip that is opposite to a first surface thereof having the first semiconductor chip stacked thereon and which includes oxygen, and
a second insulating film stacked on the first insulating film and including oxygen; or
a semiconductor chip including
a polished surface,
a first insulating film stacked on the polished surface and including oxygen,
a second insulating film stacked on the first insulating film and including oxygen, and
a semiconductor active element.
